(19) United States
(12) Patent Application Publication
(10) Pub. No.: US 2023/0056095 A1
(43) Pub. Date: Feb. 23, 2023

(54) SEMICONDUCTOR DEVICE AND METHOD FOR FABRICATING THE SAME

(71) Applicant: Samsung Electronics Co., Ltd., Suwon-si (KR)

(72) Inventors: Nam Kyu CHO, Yongin-si (KR); Sang Gil LEE, Asan-si (KR); Seok Hoon KIM, Suwon-si (KR); Yong Seung KIM, Seongnam-si (KR); Jung Taek KIM, Yongin-si (KR); Pan Kwi PARK, Incheon (KR); Dong Suk SHIN, Suwon-si (KR); Si Hyung LEE, Hwaseong-si (KR); Yang XU, Suwon-si (KR)

(21) Appl. No.: 17/734,564

(22) Filed: May 2, 2022

(30) Foreign Application Priority Data
Aug. 19, 2021 (KR) 10-2021-0109331

(51) Int. Cl. H01L 29/778; H01L 29/78; H01L 29/423

(52) U.S. Cl. CPC H01L 29/7788; H01L 29/7848; H01L 29/42316

(57) ABSTRACT

A semiconductor device includes a substrate including a first region and a second region, a first active pattern on the first region, a first gate structure having a first width in the first direction, on the first active pattern, a first epitaxial pattern disposed in the first active pattern on a side surface of the first gate structure, a second active pattern on the second region, a second gate structure having a second width greater than the first width in the first direction, on the second active pattern and a second epitaxial pattern disposed in the second active pattern on a side surface of the second gate structure. Each of the first epitaxial pattern and the second epitaxial pattern includes silicon germanium (SiGe), and a first Ge concentration of the first epitaxial pattern is lower than a second Ge concentration of the second epitaxial pattern.

### CROSS-REFERENCE TO RELATED APPLICATION(S)

This application claims priority under 35 U.S.C. § 119 to Korean Patent Application No. 10-2021-0109331 filed on Aug. 19, 2021, in the Korean Intellectual Property Office, the disclosure of which is herein incorporated by reference in its entirety.

### BACKGROUND

### 1. Technical Field

The present disclosure relates to a semiconductor device and a method for fabricating the same. More specifically, the present disclosure relates to a semiconductor device including an epitaxial pattern, and a method for fabricating the same.

### 2. Description of the Related Art

As one of scaling technologies for increasing a density of an integrated circuit device, a multi-gate transistor in which a silicon body having a fin shape, a nanowire shape, or a nanosheet shape is formed on a substrate and gates are formed on a surface of the silicon body has been proposed.

Such a multi-gate transistor uses a three-dimensional channel, and it is thus easy to perform scaling. In addition, a current control capability may be improved without decreasing a gate length of the multi-gate transistor. Furthermore, a short channel effect (SCE) that a potential of a channel region is affected by a drain voltage may be effectively suppressed by optimizing Ge concentration of the epitaxial pattern.

### SUMMARY

Aspects of the present disclosure provide a semiconductor device having improved performance.

Aspects of the present disclosure also provide a method for fabricating a semiconductor device capable of fabricating a semiconductor device having improved performance.

According to some aspects of the present inventive concept, there is provided a semiconductor device comprising a substrate including a first region and a second region, a first active pattern extending in a first direction, on the first region, a first gate structure extending in a second direction crossing the first direction and having a first width in the first direction, on the first active pattern, a first epitaxial pattern disposed in the first active pattern on a side surface of the first gate structure, a second active pattern extending in the first direction, on the second region, a second gate structure extending in the second direction and having a second width greater than the first width in the first direction, on the second active pattern and a second epitaxial pattern disposed in the second active pattern on a side surface of the second gate structure. Each of the first epitaxial pattern and the second epitaxial pattern includes silicon germanium (SiGe). The first epitaxial pattern may have a first Ge concentration and the second epitaxial pattern may have a second Ge concentration higher than the first Ge concentration.

According to some aspects of the present inventive concept, there is provided a semiconductor device comprising a substrate including a first region and a second region, a first gate structure and a second gate structure arranged along a first direction and each extending in a second direction crossing the first direction, on the first region, a first epitaxial pattern disposed on the substrate between the first gate structure and the second gate structure, a third gate structure and a fourth gate structure arranged along the first direction and each extending in the second direction, on the second region, and a second epitaxial pattern disposed on the substrate between the third gate structure and the fourth gate structure. A first distance by which the first gate structure and the second gate structure are spaced apart from each other in the first direction is smaller than a second distance by which the third gate structure and the fourth gate structure are spaced apart from each other in the first direction. Each of the first epitaxial pattern and the second epitaxial pattern includes silicon germanium (SiGe), The first epitaxial pattern may have a first Ge concentration and the second epitaxial pattern may have a second Ge concentration higher than the first Ge concentration.

According to some aspects of the present inventive concept, there is provided a semiconductor device comprising a substrate including a first region and a second region, a first active pattern and a second active pattern each extending side by side in a first direction, on the first region, a first gate structure extending in a second direction crossing the first direction, on the first active pattern and the second active pattern, a first epitaxial pattern disposed in the first active pattern on a side surface of the first gate structure, a third active pattern and a fourth active pattern extending side by side in the first direction, on the second region, a second gate structure extending in the second direction, on the third active pattern and the fourth active pattern, and a second epitaxial pattern disposed in the third active pattern on a side surface of the second gate structure. A first distance by which the first active pattern and the second active pattern are spaced apart from each other in the second direction is smaller than a second distance by which the third active pattern and the fourth active pattern are spaced apart from each other in the second direction. Each of the first epitaxial pattern and the second epitaxial pattern includes silicon germanium (SiGe), The first epitaxial pattern may have a first Ge concentration and the second epitaxial pattern may have a second Ge concentration higher than the first Ge concentration.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail exemplary embodiments thereof with reference to the attached drawings.

FIG. 1 is a layout diagram for describing a semiconductor device according to some exemplary embodiments.

FIG. 2 is a cross-sectional view taken along line A1-A1 and line A2-A2 of FIG. 1 according to example embodiments.

FIG. 3 is a cross-sectional view taken along line B1-B1 and line B2-B2 of FIG. 1 according to example embodiments.

FIG. 4 is a cross-sectional view taken along line C1-C1 and line C2-C2 of FIG. 1 according to example embodiments.

FIGS. 5 and 6 are cross-sectional views for describing a semiconductor device according to some exemplary embodiments.

FIGS. 7 to 9 are cross-sectional views for describing a semiconductor device according to some exemplary embodiments.

FIGS. 10 and 11 are cross-sectional views for describing a semiconductor device according to some exemplary embodiments.

FIG. 12 is a layout diagram for describing a semiconductor device according to some exemplary embodiments.

FIG. 13 is a cross-sectional view taken along line D1-D1 and line D2-D2 of FIG. 12 according to example embodiments.

FIG. 14 is a layout diagram for describing a semiconductor device according to some exemplary embodiments.

FIG. 15 is a cross-sectional view taken along line A1-A1, line A2-A2, line A3-A3, and line A4-A4 of FIG. 14 according to example embodiments.

FIGS. 16 to 24 are intermediate step drawings for describing a method for fabricating a semiconductor device according to some exemplary embodiments.

### DETAILED DESCRIPTION OF THE EMBODIMENTS

In the present specification, the terms “first”, “second”, and the like are used to describe various elements or components, but these elements or components are not limited by these terms. These terms are used only in order to distinguish one element or component from another element or component. Therefore, a first element or component mentioned below may be a second element or component within the technical spirit of the present disclosure.

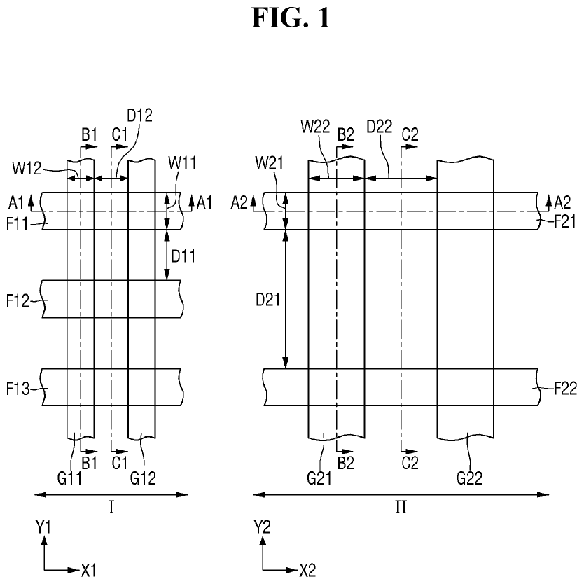

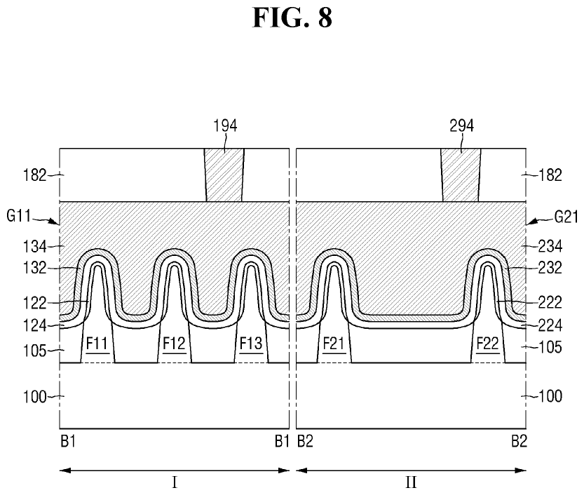

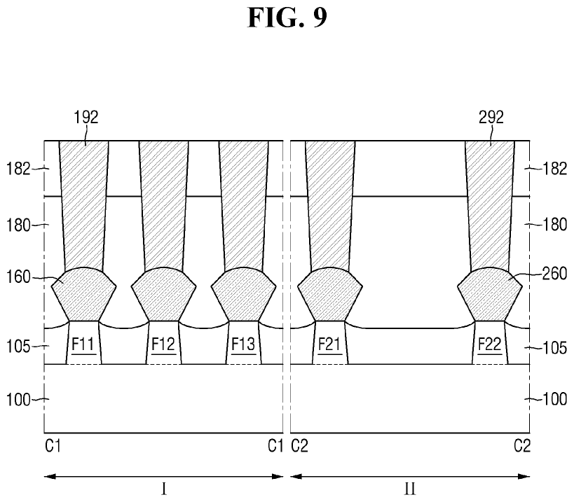

Hereinafter, a semiconductor device according to exemplary embodiments will be described with reference to FIGS. 1 to 15.

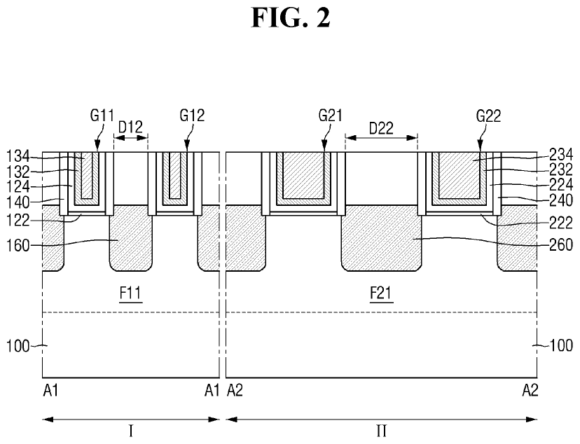

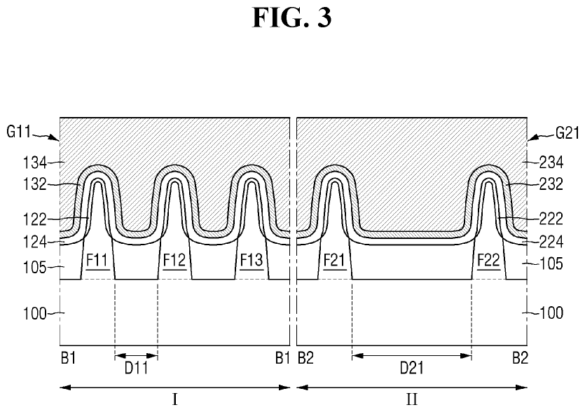

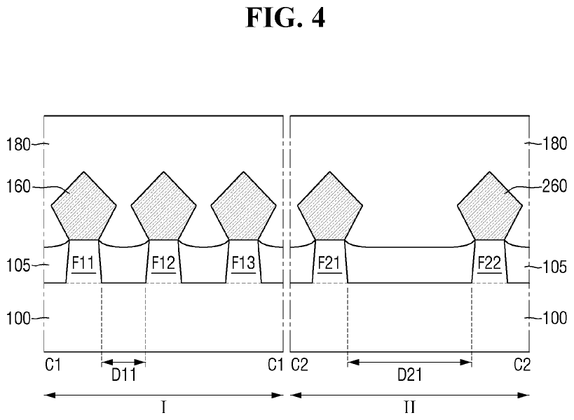

FIG. 1 is a layout diagram for describing a semiconductor device according to some exemplary embodiments. FIG. 2 is a cross-sectional view taken along line A1-A1 and line A2-A2 of FIG. 1 according to example embodiments. FIG. 3 is a cross-sectional view taken along line B1-B1 and line B2-B2 of FIG. 1 according to example embodiments. FIG. 4 is a cross-sectional view taken along line C1-C1 and line C2-C2 of FIG. 1 according to example embodiments.

Referring to FIGS. 1 to 4, the semiconductor device according to some exemplary embodiments includes a substrate 100, a field insulating film 105, first to third active patterns F11 to F13, first and second gate structures G11 and G12, first epitaxial patterns 160, fourth and fifth active patterns F21 and F22, third and fourth gate structures G21 and G22, second epitaxial patterns 260, and a first interlayer insulating film 180.

The substrate 100 may be bulk silicon or silicon-on-insulator (SOI). Alternatively, the substrate 100 may be a silicon substrate or may include other materials such as silicon germanium, silicon germanium on insulator (SGOI), indium antimonide, lead tellurium compound, indium arsenide, indium phosphide, gallium arsenide, or gallium antimonide, but is not limited thereto. For convenience of explanation, a case where the substrate 100 is a silicon substrate will hereinafter be described.

The substrate 100 may include a first region I and a second region II. The first region I and the second region II may be regions spaced apart from each other or may be regions connected to each other. In some exemplary embodiments, the first region I may be a region implemented with a higher degree of integration than the second region II. As an example, the first region I may be a logic region or a static random access memory (SRAM) region. In this case, logic circuits may be disposed in the logic region or SRAM memory cells and/or SRAM circuits may be disposed in the SRAM region. As an example, the second region II may be an input/output (I/O) region. In this case, I/O circuits may be disposed in the I/O region. As another example, the first region I may be a single gate or solution gated field effect transistor (SGFET) region of a logic element, and the second region II may be an extra gate or extended gate field effect transistor (EGFET) region. In this case, a plurality of SGFETs may be disposed in the SGFET region and a plurality of EGFETs may be disposed in the EGFET region. For example, each of the SGFETs may be a short channel transistor and each of the EGFETs may be a long channel transistor.

The first to third active patterns F11 to F13 may be formed on the first region I of the substrate 100. The first to third active patterns F11 to F13 may be adjacent to each other and extend side by side. For example, the first to third active patterns F11 to F13 may extend in a first direction X1 parallel to an upper surface of the substrate 100. In addition, the first to third active patterns F11 to F13 may be arranged along a second direction Y1 parallel to the upper surface of the substrate 100 and crossing the first direction X1. In some exemplary embodiments, the first to third active patterns F11 to F13 may be fin patterns protruding from the upper surface of the substrate 100 and extending to be elongated in the first direction X1.

The fourth and fifth active patterns F21 and F22 may be formed on the second region II of the substrate 100. The fourth and fifth active patterns F21 and F22 may be adjacent to each other and extend side by side. For example, the fourth and fifth active patterns F21 and F22 may extend in a third direction X2 parallel to the upper surface of the substrate 100. It has been illustrated that the third direction X2 is the same as the first direction X1, but this is only an example, and the third direction X2 may also be a direction different from the first direction X1. In addition, the fourth and fifth active patterns F21 and F22 may be arranged along a fourth direction Y2 parallel to the upper surface of the substrate 100 and crossing the third direction X2. In some exemplary embodiments, the fourth and fifth active patterns F21 and F22 may be fin patterns protruding from the upper surface of the substrate 100 and extending to be elongated in the third direction X2.

The active patterns F11 to F13, F21, and F22 may be portions of the substrate 100 or may include epitaxial layers grown from the substrate 100. Each of the active patterns F11 to F13, F21, and F22 may include, for example, silicon or germanium, which is an elemental semiconductor material. In addition, each of the active patterns F11 to F13, F21, and F22 may include a compound semiconductor such as a group IV-IV compound semiconductor or a group III-V compound semiconductor.

Specifically, for example, when each of the active patterns F11 to F13, F21, and F22 includes the group IV-IV compound semiconductor, each of the active patterns F11 to F13, F21, and F22 may include a binary compound or a ternary compound including two or more of carbon (C), silicon (Si), germanium (Ge), and tin (Sn), or a compound obtained by doping carbon (C), silicon (Si), germanium (Ge), and tin (Sn) with a group IV element. For example, when each of the active patterns F11 to F13, F21, and F22 includes the group III-V compound semiconductor, each of the active patterns F11 to F13, F21, and F22 may include one of a binary compound, a ternary compound, or a quaternary compound formed by combining at least one of aluminum (Al), gallium (Ga), and indium (In), which are group III elements, with one of phosphorus (P), arsenic (As), and antimony (Sb), which are group V elements. For convenience of explanation, it will hereinafter be described that the active patterns F11 to F13, F21, and F22 are silicon patterns.

The field insulating film 105 may be formed on the first region I and the second region II of the substrate 100. The field insulating film 105 may cover at least portions of side surfaces of the respective active patterns F11 to F13, F21, and F22. For example, as illustrated in FIGS. 3 and 4, portions of the respective active patterns F11 to F13, F21, and F22 may protrude above the field insulating film 105. The active patterns F11 to F13, F21, and F22 may be spaced apart from each other by the field insulating film 105.

The field insulating film 105 may include, for example, at least one of silicon oxide (SiO₂), silicon oxynitride (SiON), silicon oxycarbonitride (SiOCN), and combinations thereof, but is not limited thereto.

In some exemplary embodiments, a pitch of the first to third active patterns F11 to F13 formed on the first region I may be smaller than a pitch of the fourth and fifth active patterns F21 and F22 formed on the second region II. For example, a first distance D11 by which the first active pattern F11 and the second active pattern F12 are spaced apart from each other in the second direction Y1 may be smaller than a second distance D21 by which the fourth active pattern F21 and the fifth active pattern F22 are spaced apart from each other in the fourth direction Y2.

In some exemplary embodiments, the respective active patterns F11 to F13, F21, and F22 may have the same width. In the present specification, the term “same” means not only the completely same, but also includes a fine difference that may occur due to a margin in a process, or the like. For example, each of the first to third active patterns F11 to F13 may have a first width W11 in the second direction Y1, and each of the fourth and fifth active patterns F21 and F22 may have a second width W21 equal to the first width W11 in the fourth direction Y2. In some other exemplary embodiments, the first width W11 of each of the first to third active patterns F11 to F13 may also be different from the second width W21 of each of the fourth and fifth active patterns F21 and F22.

The first and second gate structures G11 and G12 may be formed on the first to third active patterns F11 to F13 and the field insulating film 105. The first and second gate structures G11 and G12 may be adjacent to each other and extend side by side. Each of the first and second gate structures G11 and G12 may cross the first to third active patterns F11 to F13. For example, the first and second gate structures G11 and G12 may be arranged along the first direction X1 and may extend in the second direction Y1. In some exemplary embodiments, each of the first and second gate structures G11 and G12 may include first gate electrodes 132 and 134, first gate dielectric films 124, and first gate spacers 140. In some exemplary embodiments, each of the first and second gate structures G11 and G12 may be formed of a single gate electrode having a single material.

The first gate electrodes 132 and 134 may extend long in the second direction Y1. The first gate electrodes 132 and 134 may extend along profiles of upper portions of the first to third active patterns F11 to F13 protruding above the field insulating film 105 and a profile of an upper surface of the field insulating film 105. Each of the first gate electrodes 132 and 134 may include, for example, at least one of Ti, Ta, W, Al, Co, and combinations thereof, but are not limited thereto. Each of the first gate electrodes 132 and 134 may include, for example, silicon, silicon germanium, or the like, rather than a metal.

In some exemplary embodiments, the first gate electrodes 132 and 134 may include a first work function control film 132 controlling a work function and a first filling conductive film 134 filling a space formed by the first work function control film 132. The first work function control film 132 may include, for example, at least one of TiN, TaN, TiC, TaC, TiAlC, and combinations thereof. The first filling conductive film 134 may include, for example, W or Al. Such first gate electrodes 132 and 134 may be formed by a replacement process, but are not limited thereto.

The first gate dielectric films 124 may be interposed between the first gate electrodes 132 and 134 and each of the first to third active patterns F11 to F13. For example, the first gate dielectric films 124 may conformally extend along the profiles of the upper portions of the first to third active patterns F11 to F13 protruding above the field insulating film 105. The first gate dielectric films 124 may also be interposed between the field insulating film 105 and the first gate electrodes 132 and 134.

The first gate dielectric films 124 may include, for example, at least one of silicon oxide, silicon oxynitride, silicon nitride, and a high-k material having a dielectric constant higher than that of the silicon oxide. The high-k material may include, for example, at least one of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof, but is not limited thereto.

The semiconductor device according to some exemplary embodiments may include a negative capacitance (NC) field effect transistor (FET) using a negative capacitor. For example, the first gate dielectric films 124 may include a ferroelectric material film having ferroelectric characteristics or a paraelectric material film having paraelectric characteristics.

The first gate spacers 140 may extend along both side surfaces of the first gate electrodes 132 and 134. The first gate spacers 140 may include, for example, at least one of silicon oxide, silicon nitride, silicon oxynitride, and combinations thereof, but are not limited thereto.

In some exemplary embodiments, the first gate dielectric films 124 may further extend along inner surfaces of the first gate spacers 140. For example, as illustrated in FIG. 2, the first gate dielectric film 124 may conformally extend along an upper surface of the first active pattern F11 and the inner surfaces of the first gate spacers 140.

Although not illustrated, each of the first and second gate structures G11 and G12 may further include first gate capping patterns. The first gate capping patterns may extend along upper surfaces of the first gate electrodes 132 and 134. Each of the first gate capping patterns may include, for example, at least one of silicon oxide, silicon nitride, silicon oxynitride, and combinations thereof, but are not limited thereto.

In some exemplary embodiments, first interface films 122 may be interposed between the first gate dielectric films 124 and each of the first to third active patterns F11 to F13. The first interface films 122 may extend along the profiles of the upper portions of the first to third active patterns F11 to F13 protruding above the field insulating film 105. In some exemplary embodiments, each of the first interface films 122 may include oxide of the first to third active patterns F11 to F13. For example, the first interface films 122 may include silicon oxide, but are not limited thereto.

The third and fourth gate structures G21 and G22 may be formed on the fourth and fifth active patterns F21 and F22 and the field insulating film 105. The third and fourth gate structures G21 and G22 may be adjacent to each other and extend side by side. Each of the third and fourth gate structures G21 and G22 may cross the fourth and fifth active patterns F21 to F22. For example, the third and fourth gate structures G21 and G22 may be arranged along the third direction X2 and may extend in the fourth direction Y2. In some exemplary embodiments, each of the third and fourth gate structures G21 and G22 may include second gate electrodes 232 and 234, second gate dielectric films 224, and second gate spacers 240.

The second gate electrodes 232 and 234 may extend long in the fourth direction Y2. The second gate electrodes 232 and 234 may extend along profiles of upper portions of the fourth and fifth active patterns F21 and F22 protruding above the field insulating film 105 and a profile of an upper surface of the field insulating film 105. Each of the second gate electrodes 232 and 234 may include, for example, at least one of Ti, Ta, W, Al, Co, and combinations thereof, but are not limited thereto. Each of the second gate electrodes 232 and 234 may include, for example, silicon, silicon germanium, or the like, rather than a metal.

In some exemplary embodiments, the second gate electrodes 232 and 234 may include a second work function control film 232 controlling a work function and a second filling conductive film 234 filling a space formed by the second work function control film 232. The second work function control film 232 may include, for example, at least one of TiN, TaN, TiC, TaC, TiAlC, and combinations thereof. The second filling conductive film 234 may include, for example, W or Al. Such second gate electrodes 232 and 234 may be formed by a replacement process, but are not limited thereto.

The second gate dielectric films 224 may be interposed between the second gate electrodes 232 and 234 and each of the fourth and fifth active patterns F21 and F22. For example, the second gate dielectric films 224 may conformally extend along the profiles of the upper portions of the fourth and fifth active patterns F21 and F22 protruding above the field insulating film 105. The second gate dielectric films 224 may also be interposed between the field insulating film 105 and the second gate electrodes 232 and 234.

The second gate dielectric films 224 may include, for example, at least one of silicon oxide, silicon oxynitride, silicon nitride, and a high-k material having a dielectric constant higher than that of the silicon oxide.

The semiconductor device according to some exemplary embodiments may include an NC FET using a negative capacitor. For example, the second gate dielectric films 224 may include a ferroelectric material film having ferroelectric characteristics and a paraelectric material film having paraelectric characteristics.

The second gate spacers 240 may extend along both side surfaces of the second gate electrodes 232 and 234. The second gate spacers 240 may include, for example, at least one of silicon oxide, silicon nitride, silicon oxynitride, and combinations thereof, but are not limited thereto.

In some exemplary embodiments, the second gate dielectric films 224 may further extend along inner surfaces of the second gate spacers 240. For example, as illustrated in FIG. 2, the second gate dielectric film 224 may conformally extend along an upper surface of the fourth active pattern F21 and the inner surfaces of the second gate spacers 240.

Although not illustrated, each of the third and fourth gate structures G21 and G22 may further include second gate capping patterns. The second gate capping patterns may extend along upper surfaces of the second gate electrodes 232 and 234. Each of the second gate capping patterns may include, for example, at least one of silicon oxide, silicon nitride, silicon oxynitride, and combinations thereof, but are not limited thereto.

In some exemplary embodiments, second interface films 222 may be interposed between the second gate dielectric films 224 and each of the fourth and fifth active patterns F21 and F22. The second interface films 222 may extend along the profiles of the upper portions of the fourth and fifth active patterns F21 and F22 protruding above the field insulating film 105. In some exemplary embodiments, each of the second interface films 222 may include oxide of the fourth and fifth active patterns F21 and F22. For example, the second interface films 222 may include silicon oxide, but are not limited thereto.

In some exemplary embodiments, a pitch of the first and second gate structures G11 to G12 formed on the first region I may be smaller than a pitch of the third and fourth G21 and G22 formed on the second region II. For example, a third distance D12 by which the first gate structure G11 and the second gate structure G12 are spaced apart from each other in the first direction X1 may be smaller than a fourth distance D22 by which the third gate structure G21 and the fourth gate structure G22 are spaced apart from each other in the third direction X2.

In some exemplary embodiments, a channel length of each of the active patterns F11 to F13 may be smaller than a channel length of each of the fourth and fifth active patterns F21 and F22. For example, each of the first and second gate structures G11 and G12 may have a third width W12 in the first direction X1, and each of the third and fourth gate structures G21 and G22 may have a fourth width W22 greater than the third width W12 in the third direction X2. As an example, the third width W12 may be about 5 nm to about 30 nm, and the fourth width W22 may be about 50 nm to about 200 nm. Preferably, the third width W12 may be about 10 nm to about 15 nm, and the fourth width W22 may be about 70 nm to about 150 nm.

The first epitaxial pattern 160 may be formed on at least one side surface of each of the first and second gate structures G11 and G12. In addition, the first epitaxial pattern 160 may be formed in each of the first to third active patterns F11 to F13. For example, the first epitaxial pattern 160 may be an embedded epitaxial pattern filling a recess formed in each of the first to third active patterns F11 to F13. The first epitaxial pattern 160 may be spaced apart from the first gate electrodes 132 and 134 by the first gate spacer 140. The first epitaxial pattern 160 may include an epitaxial layer formed in each of the first to third active patterns F11 to F13. For example, the first epitaxial pattern 160 may include an epitaxial layer grown from each of the first to third active patterns F11 to F13 by a selective epitaxial growth (SEG) process.

In some exemplary embodiments, the first epitaxial pattern 160 may be an elevated epitaxial pattern. For example, as illustrated in FIG. 2, a height of an upper surface of the first epitaxial pattern 160 may be greater than a height of an upper surface of each of the first to third active patterns F11 to F13, on the basis of the upper surface of the substrate 100.

The second epitaxial pattern 260 may be formed on at least one side surface of each of the third and fourth gate structures G21 and G22. In addition, the second epitaxial pattern 260 may be formed in each of the fourth and fifth active patterns F21 and F22. For example, the second epitaxial pattern 260 may be an embedded epitaxial pattern filling a recess formed in each of the fourth and fifth active patterns F21 and F22. The second epitaxial pattern 260 may be spaced apart from the second gate electrodes 232 and 234 by the second gate spacer 240. The second epitaxial pattern 260 may include an epitaxial layer formed in each of the fourth and fifth active patterns F21 and F22. For example, the second epitaxial pattern 260 may include an epitaxial layer grown from each of the fourth and fifth active patterns F21 and F22 by a selective epitaxial growth (SEG) process.

In some exemplary embodiments, the second epitaxial pattern 260 may be an elevated epitaxial pattern. For example, as illustrated in FIG. 2, a height of an upper surface of the second epitaxial pattern 260 may be greater than a height of an upper surface of each of the fourth and fifth active patterns F21 and F22, on the basis of the upper surface of the substrate 100.

In some exemplary embodiments, a size of the first epitaxial pattern 160 may be smaller than a size of the second epitaxial pattern 260. For example, as described above, the pitch of the first and second gate structures G11 to G12 formed on the first region I may be smaller than the pitch of the third and fourth G21 and G22 formed on the second region II. Accordingly, a size of the first epitaxial pattern 160 (i.e., a size of the first epitaxial pattern in the first direction X1) interposed between the first gate structure G11 and the second gate structure G12 may be smaller than a size of the second epitaxial pattern 260 (i.e., a size of the second epitaxial pattern in the third direction X2) interposed between the third gate structure G21 and the fourth gate structure G22.

In some exemplary embodiments, both the first region I of the substrate 100 and the second region II of the substrate 100 may be P-channel field effect transistor (PFET) regions. In this case, a plurality of P-channel field effect transistors (PFETs) may be disposed in each of the first region I and the second region II. For example, each of the first epitaxial pattern 160 and the second epitaxial pattern 260 may include p-type impurities or impurities for preventing diffusion of the p-type impurities. For example, each of the first epitaxial pattern 160 and the second epitaxial pattern 260 may include or be formed of at least one of B, C, In, Ga, Al, and combinations thereof.

Each of the first epitaxial pattern 160 and the second epitaxial pattern 260 may include or be formed of silicon germanium (SiGe). When the active patterns F11 to F13, F21, and F22 include silicon (Si), the first epitaxial pattern 160 and the second epitaxial pattern 260 including silicon germanium (SiGe) having a greater lattice constant than silicon (Si) may apply compressive stress to the active patterns F11 to F13, F21, and F22. As a result, carrier mobility of channel regions formed on the first region I and the second region II, which are the PFET regions, may be improved.

In example embodiments, a first Ge concentration of the first epitaxial pattern 160 may be lower than a second Ge concentration of the second epitaxial pattern 260. A difference between the first Ge concentration and the second Ge concentration may be, for example, about 5% to about 20%. As an example, the first Ge concentration of the first epitaxial pattern 160 may be about 30% to about 55%, and the second Ge concentration of the second epitaxial pattern 260 may be about 35% to about 75%. In some exemplary embodiments, a difference between the first Ge concentration and the second Ge concentration may be about 5% to about 15%. In some other exemplary embodiments, a difference between the first Ge concentration and the second Ge concentration may be about 10% to about 20%.

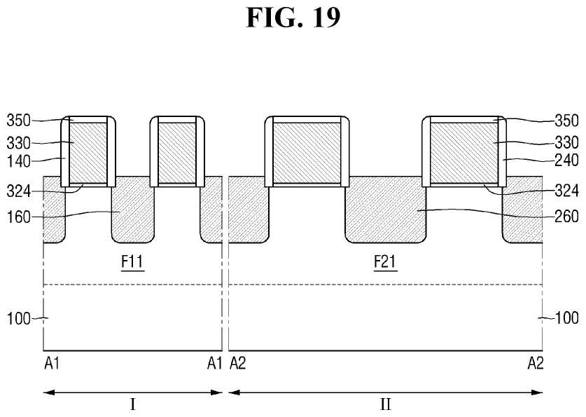

In some exemplary embodiments, the first epitaxial pattern 160 and the second epitaxial pattern 260 may be formed at the same level in a vertical direction perpendicular to an upper surface of the substrate 100. In the present specification, the term “same level” refers to formation by the same fabricating process. For example, the first epitaxial pattern 160 and the second epitaxial pattern 260 may be simultaneously formed by a selective epitaxial growth process. In this case, the difference between the first Ge concentration and the second Ge concentration may be due to a loading effect of the selective epitaxial growth process for forming the first epitaxial pattern 160 and the second epitaxial pattern 260. This will be described in more detail later in a description regarding FIGS. 19 to 22.

The first interlayer insulating film 180 may be formed on the substrate 100 and the field insulating film 105. The first interlayer insulating film 180 may cover the first and second gate structures G11 and G12, the first epitaxial patterns 160, the third and fourth gate structures G21 and G22, and the second epitaxial patterns 260.

The first interlayer insulating film 180 may include, for example, at least one of silicon oxide, silicon oxynitride, silicon nitride, and a low-k material having a dielectric constant lower than that of the silicon oxide, but is not limited thereto. The low-k material may include, for example, at least one of flowable oxide (FOX), torene silazene (TOSZ), undoped silica glass (USG), borosilica glass (BSG), phosphosilica glass (PSG), borophosphosilica glass (BPSG), plasma enhanced tetra ethyl ortho silicate (PETEOS), fluoride silicate glass (FSG), carbon doped silicon oxide (CDO), xerogel, aerogel, amorphous fluorinated carbon, organo silicate glass (OSG), parylene, bis-benzocyclobutenes (BCB), SiLK, polyimide, porous polymeric material, and combinations thereof, but is not limited thereto.

As a semiconductor device is highly integrated and diversified, a configuration of epitaxial patterns has a great influence on characteristics of the semiconductor device. The semiconductor device according to some exemplary embodiments may have improved performance by optimizing the Ge concentrations of the epitaxial patterns for each region. For example, the performance of semiconductor device may include characteristics (e.g., current-voltage (I-V) characteristic) of elements (e.g., transistors) included in the semiconductor device.

For example, in a region (e.g., the first region I) requiring a relatively high degree of integration, such as a solution-gated FET (SGFET) region or a static random access memory (SRAM) region, the first epitaxial pattern 160 having a relatively low Ge concentration may be formed in order to control element characteristics such as a short channel effect (SCE). For example, in a region (e.g., the second region II) formed with a relatively low degree of integration, such as an extended-gate FET (EGFET) region or an input/output (I/O) region, the second epitaxial pattern 260 having a relatively high Ge concentration may be formed in order to improve a Schottky barrier height, external resistance, and the like. As a result, the semiconductor device of which performance is improved by optimizing the Ge concentrations of the epitaxial patterns for each region may be provided.

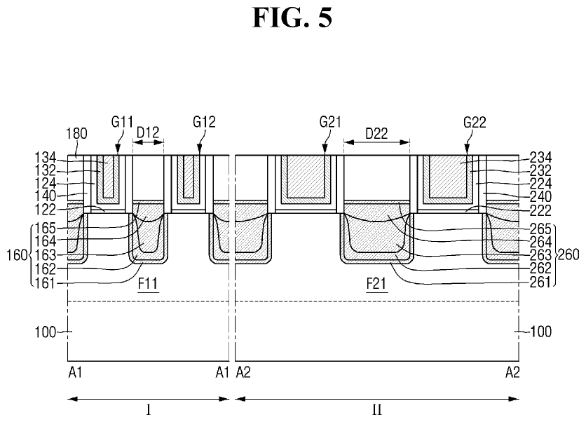

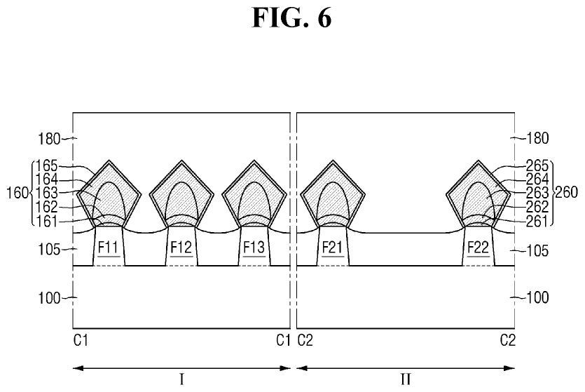

FIGS. 5 and 6 are cross-sectional views for describing a semiconductor device according to some exemplary embodiments. For convenience of explanation, portions overlapping those described above with reference to FIGS. 1 to 4 will be briefly described or a description therefor will be omitted.

Referring to FIGS. 5 and 6, in the semiconductor device according to some exemplary embodiments, each of a first epitaxial pattern 160 and a second epitaxial pattern 260 includes a plurality of epitaxial layers having various Ge concentrations.

For example, the first epitaxial pattern 160 may include first to fifth epitaxial layers 161 to 165, and the second epitaxial pattern 260 may include sixth to tenth epitaxial layers 261 to 265. Shapes of the first to fifth epitaxial layers 161 to 165 and the sixth to tenth epitaxial layers 261 to 265 are only examples, and are not limited to those illustrated in FIGS. 5 and 6. In addition, some of the first to fifth epitaxial layers 161 to 165 or some of the sixth to tenth epitaxial layers 261 to 265 may also be omitted.

The first to fifth epitaxial layers 161 to 165 may be sequentially stacked on each of the first to third active patterns F11 to F13. The first epitaxial layer 161 may be formed from each of the first to third active patterns F11 to F13 by a selective epitaxial growth (SEG) process. The first epitaxial layer 161 may function as a seed layer for forming the second to fifth epitaxial layers 162 to 165. The fifth epitaxial layer 165 may be formed to cover the first to fourth epitaxial layers 161 to 164. The fifth epitaxial layer 165 may function as a capping layer for preventing the first epitaxial pattern 160 from being excessively etched in a process of forming a contact electrically connected to the first epitaxial pattern 160.

The sixth to tenth epitaxial layers 261 to 265 may be sequentially stacked on each of the fourth and fifth active patterns F21 and F22. The sixth epitaxial layer 261 may be formed from each of the fourth and fifth active patterns F21 and F22 by a selective epitaxial growth (SEG) process. The sixth epitaxial layer 261 may function as a seed layer for forming the seventh to tenth layers 262 to 265. The tenth epitaxial layer 265 may be formed to cover the sixth to ninth epitaxial layers 261 to 264. The tenth epitaxial layer 265 may function as a capping layer for preventing the second epitaxial pattern 260 from being excessively etched in a process of forming a contact electrically connected to the second epitaxial pattern 260.

The first to fifth epitaxial layers 161 to 165 may include Ge of various concentrations. For example, Ge concentrations of the first to fourth epitaxial layers 161 to 164 may increase as the first to fourth epitaxial layers 161 to 164 become distant from each of the first to third active patterns F11 to F13. As an example, the Ge concentration of the first epitaxial layer 161 may be about 10% to about 20%, the Ge concentration of the second epitaxial layer 162 may be about 20% to about 30%, the Ge concentration of the third epitaxial layer 163 may be about 30% to about 55%, and the Ge concentration of the fourth epitaxial layer 164 may be about 55% to about 65%. In some embodiments, the fifth epitaxial layer 165 may not include Ge.

In example embodiments, Ge concentration of each of the first to fifth and the sixth to tenth epitaxial layers 161 to 165 and 261 to 265 may be controlled according to types of silicon precursors for growing silicon germanium (SiGe).

In example embodiments, the first to fifth epitaxial layers 161 to 165 may include first to fifth silicon precursors, respectively, and the sixth to tenth epitaxial layers 261 to 265 may include the first to fifth silicon precursors, respectively. For example, Ge concentrations of some of the first to fifth epitaxial layers 161 to 165 may increase as the first to fifth epitaxial layers 161 to 165 become distant from each of the first to third active patterns F11 to F13, and Ge concentrations of some of the sixth to tenth epitaxial layers 261 to 265 may increase as the sixth to tenth epitaxial layers 261 to 265 become distant from each of the fourth and fifth active patterns F21 to F22.

In example embodiments, at least one the first to fifth and sixth to tenth epitaxial layers 161 to 165 and 261 to 265 may include two or more silicon precursors.

The sixth to tenth epitaxial layers 261 to 265 may include Ge of various concentrations. For example, similar to the Ge concentrations of the first to fourth epitaxial layers 161 to 164, Ge concentrations of the sixth and ninth epitaxial layers 261 to 264 may increase as the sixth to ninth epitaxial layers 261 to 264 become distant from each of the fourth and fifth active patterns F21 to F22. In some embodiments, the tenth epitaxial layer 265 may not include Ge.

A Ge concentration of a main layer of the first epitaxial pattern 160 may be lower than a Ge concentration of a main layer of the second epitaxial pattern 260. The main layer may be, for example, an epitaxial layer occupying the largest volume among a plurality of epitaxial layers. For example, the main layer of the first epitaxial pattern 160 may be the third epitaxial layer 163 and the main layer of the second epitaxial pattern 260 may be the eighth epitaxial layer 263. For example, the Ge concentration of the third epitaxial layer 163 of the first epitaxial pattern 160 may be lower than the Ge concentration of the eighth epitaxial layer 263 of the second epitaxial pattern 260. A difference between the Ge concentration of the third epitaxial layer 163 and the Ge concentration of the eighth epitaxial layer 263 may be, for example, about 5% to about 20%. As an example, the Ge concentration of the third epitaxial layer 163 may be about 30% to about 55%, and the Ge concentration of the eighth epitaxial layer 263 may be about 35% to about 75%. In some exemplary embodiments, a difference between the Ge concentration of the third epitaxial layer 163 and the Ge concentration of the eighth epitaxial layer 263 may be about 5% to about 15%. In some other exemplary embodiments, a difference between the Ge concentration of the third epitaxial layer 163 and the Ge concentration of the eighth epitaxial layer 263 may be about 10% to about 20%.

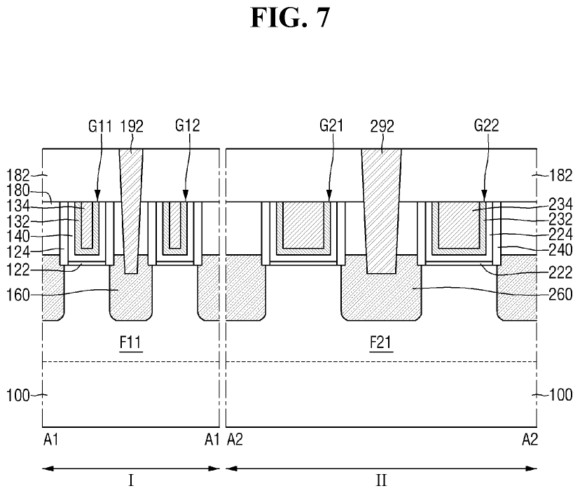

FIGS. 7 to 9 are cross-sectional views for describing a semiconductor device according to some exemplary embodiments. For convenience of explanation, portions overlapping those described above with reference to FIGS. 1 to 4 will be briefly described or a description therefor will be omitted.

Referring to FIGS. 7 to 9, the semiconductor device according to some exemplary embodiments may further include a first source/drain contact 192, a second source/drain contact 292, a first gate contact 194, and a second gate contact 294.

The first source/drain contact 192 may be electrically connected to the first epitaxial pattern 160, and the second source/drain contact 292 may be electrically connected to the second epitaxial pattern 260. For example, a second interlayer insulating film 182 covering the first interlayer insulating film 180 may be formed. The first source/drain contact 192 may penetrate through the first interlayer insulating film 180 and the second interlayer insulating film 182 to be in contact with the first epitaxial pattern 160, and the second source/drain contact 292 may penetrate through the first interlayer insulating film 180 and the second interlayer insulating film 182 to be in contact with the second epitaxial pattern 260. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact. Each of the first source/drain contact 192 and the second source/drain contact 292 may include, for example, tungsten (W), aluminum (Al), or copper (Cu), but is not limited thereto.

The first gate contact 194 may be electrically connected to the first gate electrodes 132 and 134, and the second gate contact 294 may be electrically connected to the second gate electrodes 232 and 234. For example, the second interlayer insulating film 182 covering the first interlayer insulating film 180 may be formed. The first gate contact 194 may penetrate through the first interlayer insulating film 180 and the second interlayer insulating film 182 to be in contact with the first gate electrodes 132 and 134, and the second gate contact 294 may penetrate through the first interlayer insulating film 180 and the second interlayer insulating film 182 to be in contact with the second gate electrodes 232 and 234. Each of the first gate contact 194 and the second gate contact 294 may include, for example, tungsten (W), aluminum (Al), or copper (Cu), but is not limited thereto.

It has been illustrated that each of the first source/drain contact 192, the second source/drain contact 292, the first gate contact 194, and the second gate contact 294 is a single film, but this is only an example, and each of the first source/drain contact 192, the second source/drain contact 292, the first gate contact 194, and the second gate contact 294 may be formed by stacking a plurality of conductive films. As an example, the first source/drain contact 192 may include a silicide film in contact with the first epitaxial pattern 160 and a through conductive layer formed on the silicide film and penetrate through the first interlayer insulating film 180 and the second interlayer insulating film 182. The silicide film may include, for example, platinum (Pt), nickel (Ni), or cobalt (Co), but is not limited thereto. The through conductive layer may include, for example, titanium (Ti), titanium nitride (TiN), tungsten (W), aluminum (Al), or copper (Cu), but is not limited thereto.

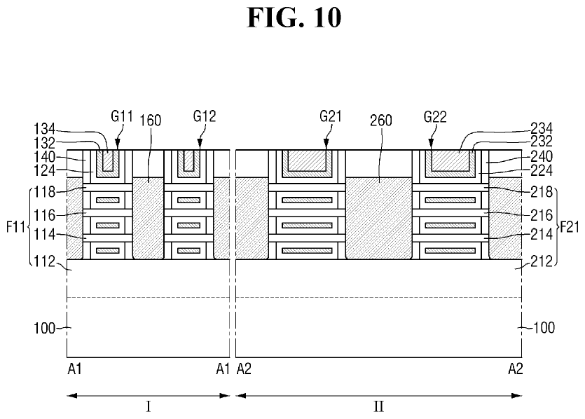

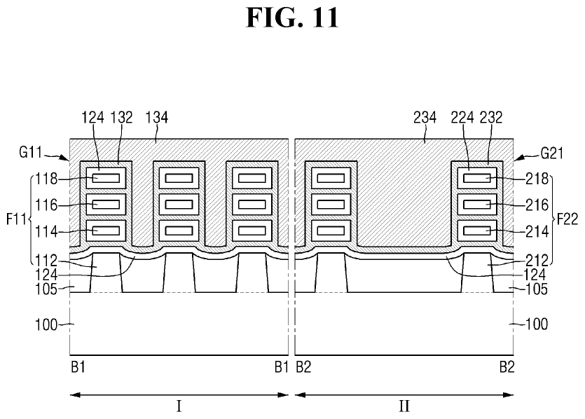

FIGS. 10 and 11 are cross-sectional views for describing a semiconductor device according to some exemplary embodiments. For convenience of explanation, portions overlapping those described above with reference to FIGS. 1 to 4 will be briefly described or a description therefor will be omitted.

Referring to FIGS. 10 and 11, in the semiconductor device according to some exemplary embodiments, each of the active patterns F11 to F13, F21, and F22 includes a plurality of sheet patterns.

For example, each of the first to third active patterns F11 to F13 may include first to third sheet patterns 114, 116, and 118 sequentially disposed on an upper surface of the substrate 100 and spaced apart from each other. Each of the first to third sheet patterns 114, 116, and 118 may extend in the first direction X1 to penetrate through the first gate structure G11 and the second gate structure G12. For example, each of the first gate structure G11 and the second gate structure G12 may surround the first to third sheet patterns 114, 116, and 118.

In addition, for example, each of the fourth and fifth active patterns F21 and F22 may include fourth to sixth sheet patterns 214, 216, and 218 sequentially disposed on the upper surface of the substrate 100 and spaced apart from each other. Each of the fourth to sixth sheet patterns 214, 216, and 218 may extend in the third direction X2 to penetrate through the third gate structure G21 and the fourth gate structure G22. For example, each of the third gate structure G21 and the fourth gate structure G22 may surround the fourth to sixth sheet patterns 214, 216, and 218.

It has been illustrated in FIG. 11 that a cross section of each of the sheet patterns 114, 116, 118, 214, 216 and 218 has a rectangular shape, but this is only an example. As another example, a cross section of each of the sheet patterns 114, 116, 118, 214, 216, and 218 may have a circular or other polygonal shape.

In some exemplary embodiments, each of the first to third active patterns F11 to F13 may further include a first fin pattern 112 protruding from the upper surface of the substrate 100 and extending in the first direction X1. The first to third sheet patterns 114, 116, and 118 may be sequentially disposed on an upper surface of the first fin pattern 112.

In some exemplary embodiments, each of the fourth and fifth active patterns F21 and F22 may further include a second fin pattern 212 protruding from the upper surface of the substrate 100 and extending in the third direction X2. The fourth to sixth sheet patterns 214, 216, and 218 may be sequentially disposed on an upper surface of the second fin pattern 212.

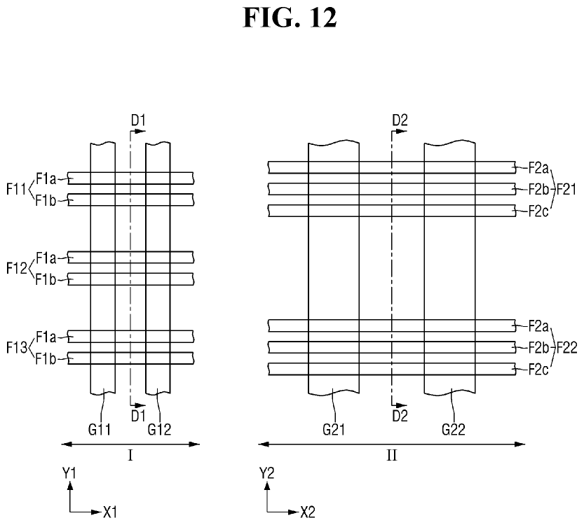

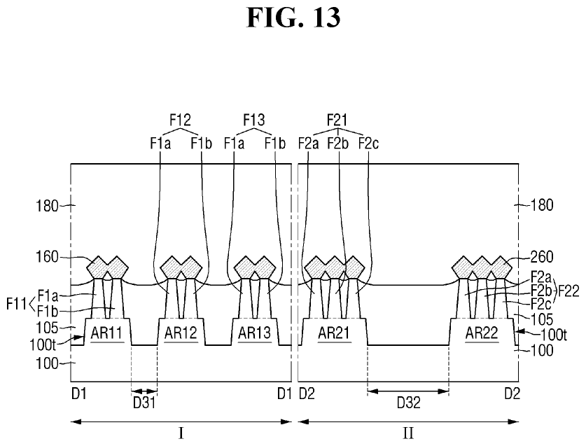

FIG. 12 is a layout diagram for describing a semiconductor device according to some exemplary embodiments. FIG. 13 is a cross-sectional view taken along line D1-D1 and line D2-D2 of FIG. 12 according to example embodiments. For convenience of explanation, portions overlapping those described above with reference to FIGS. 1 to 4 will be briefly described or a description therefor will be omitted.

Referring to FIGS. 12 and 13, each of the active patterns F11 to F13, F21, and F22 may include a plurality of sub-patterns.

For example, each of the first to third active patterns F11 to F13 may include first and second sub-patterns F1a and F1b adjacent to each other and extending side by side. Each of the first and second sub-patterns F1a and F1b may extend in the first direction X1 to cross the first gate structure G11 and the second gate structure G12.

In addition, for example, each of the fourth and fifth active patterns F21 and F22 may include third to fifth sub-patterns F2a to F2c adjacent to each other and extending side by side. Each of the third to fifth sub-patterns F2a to F2c may extend in the third direction X2 to cross the third gate structure G21 and the fourth gate structure G22.

In some exemplary embodiments, the substrate 100 may include first active regions AR11 to AR13 on the first region I and second active regions AR21 and AR22 on the second region II. The first active regions AR11 to AR13 and the second active regions AR21 and AR22 may be defined by element isolation trenches 100t in the substrate 100. The element isolation trench 100t may be a deep trench formed in the substrate 100. The first active regions AR11 to AR13 and the second active regions AR21 and AR22 may be isolated from each other by the element isolation trench 100t. For example, the field insulating film 105 may fill the element isolation trenches 100t. The first and second sub-patterns F1a and F1b may be disposed on each of the first active regions AR11 to AR13. The third to fifth sub-patterns F2a to F2c may be disposed on each of the second active regions AR21 and AR22.

In some exemplary embodiments, a pitch of the first active regions AR11 to AR13 formed on the first region I may be smaller than a pitch of the second active regions AR21 and Ar22 formed on the second region II. For example, a fifth distance D31 by which the first active regions AR11 and AR12 are spaced apart from each other in the second direction Y1 may be smaller than a sixth distance D32 by which the second active regions AR21 and AR22 are spaced apart from each other in the fourth direction Y2.

In some exemplary embodiments, the first epitaxial pattern 160 may be an epitaxial pattern merged with respect to the first and second sub-patterns F1a and F1b. For example, the first epitaxial pattern 160 may have a form in which epitaxial layers grown from the first and second sub-patterns F1a and F1b, respectively, are merged with each other. Unlike in FIG. 13, in some other exemplary embodiments, the epitaxial layers grown from the first and second sub-patterns F1a and F1b may not be merged with each other.

In some exemplary embodiments, the second epitaxial pattern 260 may be an epitaxial pattern merged with respect to the third to fifth sub-patterns F2a to F2c. For example, the second epitaxial pattern 260 may have a form in which epitaxial layers grown from the third to fifth sub-patterns F2a to F2c, respectively, are merged with each other. Unlike in FIG. 13, in some other exemplary embodiments, the epitaxial layers grown from the third to fifth sub-patterns F2a to F2c may not be merged with each other.

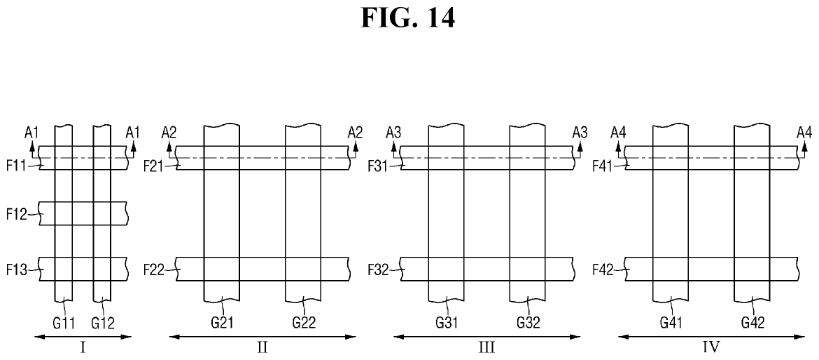

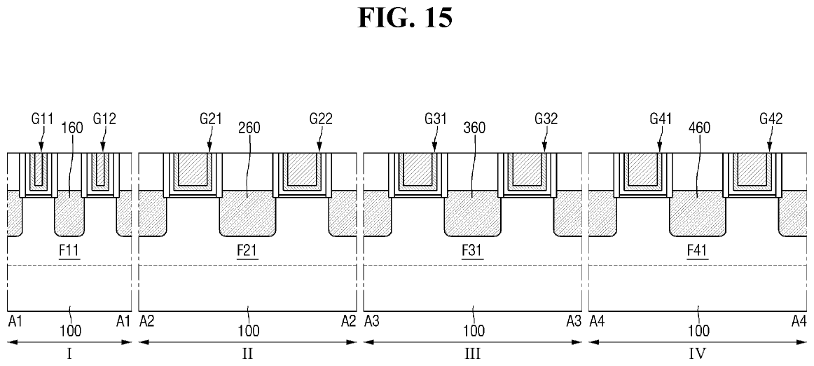

FIG. 14 is a layout diagram for describing a semiconductor device according to some exemplary embodiments. FIG. 15 is a cross-sectional view taken along line A1-A1, line A2-A2, line A3-A3, and line A4-A4 of FIG. 14 according to example embodiments. For convenience of explanation, portions overlapping those described above with reference to FIGS. 1 to 4 will be briefly described or a description therefor will be omitted.

Referring to FIGS. 14 and 15, in the semiconductor device according to some exemplary embodiments, the substrate 100 includes first to fourth regions I to IV.

The first to fourth regions I to IV may be regions spaced apart from each other or may be regions connected to each other. In some exemplary embodiments, the second to fourth regions II to IV may be regions implemented with a lower degree of integration than the first region I. For example, the first region I may be an SGFET region or an SRAM region, and the second to fourth regions II to IV may be EGFET regions or input/output (I/O) regions.

Sixth and seventh active patterns F31 and F32, fifth and sixth gate structures G31 and G32, and a third epitaxial pattern 360 may be formed on the third region III of the substrate 100. The sixth and seventh active patterns F31 and F32 may be similar to the fourth and fifth active patterns F21 and F22, the fifth and sixth gate structures G31 and G32 may be similar to the third and fourth gate structures G21 and G22, the third epitaxial pattern 360 may be similar to the second epitaxial pattern 260, and a detailed description therefor will thus be omitted below.

Eighth and ninth active patterns F41 and F42, seventh and eighth gate structures G41 and G42, and a fourth epitaxial pattern 460 may be formed on the fourth region IV of the substrate 100. The eighth and ninth active patterns F41 and F42 may be similar to the fourth and fifth active patterns F21 and F22, the seventh and eighth gate structures G41 and G42 may be similar to the third and fourth gate structures G21 and G22, the fourth epitaxial pattern 460 may be similar to the second epitaxial pattern 260, and a detailed description therefor will thus be omitted below.

In some exemplary embodiments, the second, third, and fourth epitaxial patterns 260, 360, and 460 may have different Ge concentrations. For example, the second Ge concentration of the second epitaxial pattern 260 may be lower than a third Ge concentration of the third epitaxial pattern 360, and the third Ge concentration may be lower than a fourth Ge concentration of the fourth epitaxial pattern 460. As an example, the second Ge concentration of the second epitaxial pattern 260 may be about 30% to about 55%, the third Ge concentration of the third epitaxial pattern 360 may be about 35% to about 70%, and the fourth Ge concentration of the fourth epitaxial pattern 460 may be about 40% to about 75%.

In some exemplary embodiments, a difference between the first Ge concentration of the first epitaxial pattern 160 and the second Ge concentration of the second epitaxial pattern 260 may be about 0% to about 5%. In some exemplary embodiments, a difference between the first Ge concentration of the first epitaxial pattern 160 and the third Ge concentration of the third epitaxial pattern 360 may be about 5% to about 15%. In some exemplary embodiments, a difference between the first Ge concentration of the first epitaxial pattern 160 and the fourth Ge concentration of the fourth epitaxial pattern 460 may be about 10% to about 20%.

The differences between the first Ge concentration and the second to fourth Ge concentrations may be due to a loading effect of a selective epitaxial growth process for forming the first epitaxial pattern 160 and the second, third, and fourth epitaxial patterns 260, 360, and 460. This will be described in more detail later in a description regarding FIGS. 19 to 22.

Hereinafter, a method for fabricating a semiconductor device according to exemplary embodiments will be described with reference to FIGS. 1 to 24.

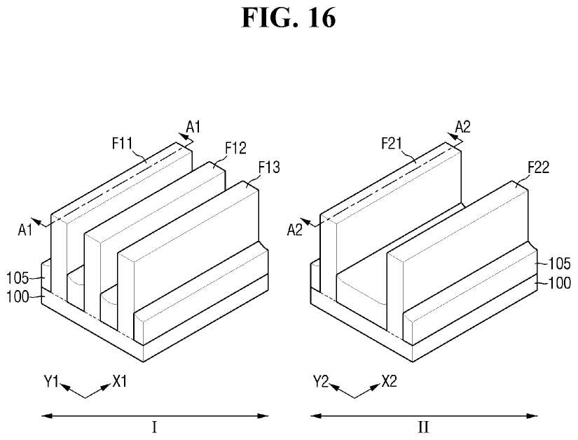

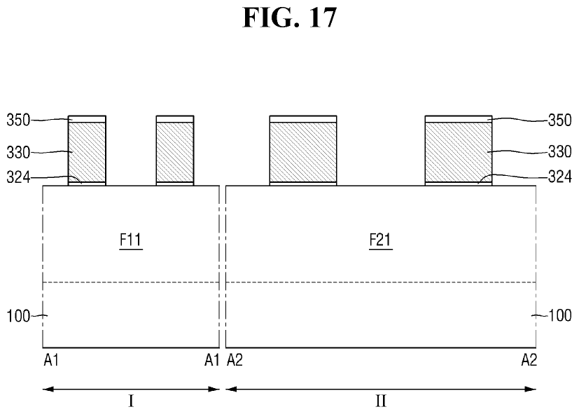

FIGS. 16 to 24 are intermediate step drawings for describing a method for fabricating a semiconductor device according to some exemplary embodiments. For convenience of explanation, portions overlapping those described above with reference to FIGS. 1 to 15 will be briefly described or a description therefor will be omitted. For reference, a description for FIGS. 17 to 19, 23, and 24 will be provided using cross-sectional views taken along lines A1-A1 and A2-A2 of FIG. 16.

Referring to FIG. 16, active patterns F11 to F13, F21, and F22 are formed on a substrate 100.

The active patterns F11 to F13, F21, and F22 may be portions of the substrate 100 or may include epitaxial layers grown from the substrate 100. The substrate 100 may include a first region I and a second region II. First to third active patterns F11 to F13 may be formed on the first region I of the substrate 100, and fourth and fifth active patterns F21 and F22 may be formed on the second region II of the substrate 100. In some exemplary embodiments, the first region I may be a region implemented with a higher degree of integration than the second region II.

Then, a field insulating film 105 may be formed on the first region I and the second region II of the substrate 100. The field insulating film 105 may cover at least portions of side surfaces of the respective active patterns F11 to F13, F21, and F22. The field insulating film 105 may include, for example, at least one of silicon oxide (SiO₂), silicon oxynitride (SiON), silicon oxycarbonitride (SiOCN), and combinations thereof, but is not limited thereto.

Referring to FIG. 17, dummy gate structures 324 and 330 are formed on the active patterns F11 to F13, F21, and F22 and the field insulating film 105.

The dummy gate structures 324 and 330 may be formed by, for example, an etching process using a mask pattern 350. The dummy gate structures 324 and 330 on the first region I may cross the first to third active patterns F11 to F13, and the dummy gate structures 324 and 330 on the second region II may cross the fourth and fifth active patterns F21 and F22.

In some exemplary embodiments, each of the dummy gate structures 324 and 330 may include a dummy gate electrode 330 and a dummy gate dielectric film 324. The dummy gate electrode 330 may include or be formed of, for example, polysilicon or amorphous silicon, but is not limited thereto. The dummy gate dielectric film 324 may be interposed between the dummy gate electrode 330 and each of the active patterns F11 to F13, F21, and F22. The dummy gate dielectric film 324 may be, for example, a silicon oxide film, but is not limited thereto.

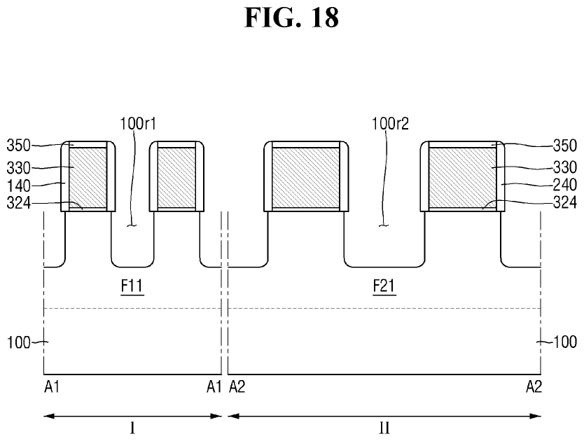

Referring to FIG. 18, first gate spacers 140 and second gate spacers 240 are formed on side surfaces of the dummy gate structures 324 and 330.

The first gate spacers 140 may be formed on side surfaces of the dummy gate structures 324 and 330 on the first region I, and the second gate spacers 240 may be formed on side surfaces of the dummy gate structures 324 and 330 on the second region II.

In a process of forming the first gate spacers 140, a portion of each of the first to third active patterns F11 to F13 is removed, such that a first recess 100r1 may be formed. The first recess 100r1 may be formed on at least one side surface of the dummy gate structures 324 and 330 on the first region I. In addition, in a process of forming the second gate spacers 240, a portion of each of the fourth and fifth active patterns F21 and F22 is removed, such that a second recess 100r2 may be formed. The second recess 100r2 may be formed on at least one side surface of the dummy gate structures 324 and 330 on the second region II.

Referring to FIG. 19, a first epitaxial pattern 160 and a second epitaxial pattern 260 are formed.

For example, a selective epitaxial growth (SEG) process of filling the first recess 100r1 and the second recess 100r2 of FIG. 18 may be performed. As a result, the first epitaxial pattern 160 may be formed in each of the first to third active patterns F11 to F13, and the second epitaxial pattern 260 may be formed in each of the fourth and fifth active patterns F21 and F22. In some exemplary embodiments, the first epitaxial pattern 160 and the second epitaxial pattern 260 may be formed at the same level. For example, the first epitaxial pattern 160 and the second epitaxial pattern 260 may be simultaneously formed by a selective epitaxial growth process.

Each of the first epitaxial pattern 160 and the second epitaxial pattern 260 may include silicon germanium (SiGe). In this case, a first Ge concentration of the first epitaxial pattern 160 may be lower than a second Ge concentration of the second epitaxial pattern 260. This may be due to a loading effect of the selective epitaxial growth process. For example, as described above, the first region I in which the first epitaxial pattern 160 is formed may be a region realized with a higher degree of integration than the second region II. In this case, a composition ratio of silicon germanium (SiGe) grown on the first region I may be different from the composition ratio of silicon germanium (SiGe) grown on the second region II. As an example, in order to grow silicon germanium (SiGe), silicon (Si) precursors and germanium (Ge) precursors may be provided in-situ. In this case, a growth rate of silicon (Si) may be faster in the first region I than in the second region II, or a growth rate of germanium (Ge) may be faster in the second region II than in the first region I.

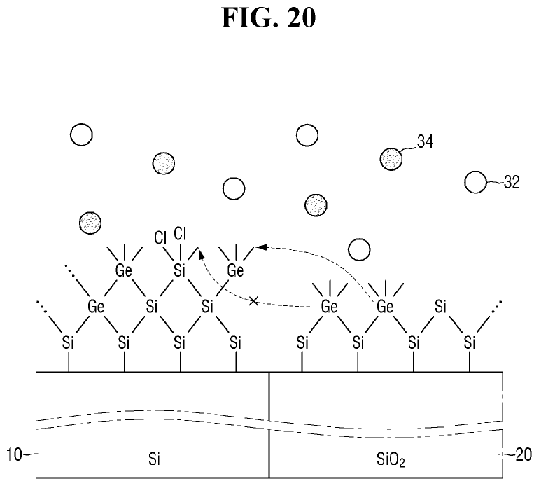

Referring to FIGS. 20 to 22, in the method for fabricating a semiconductor device according to some exemplary embodiments, a difference between the first Ge concentration of the first epitaxial pattern 160 and the second Ge concentration of the second epitaxial pattern 260 may be controlled according to types of silicon precursors for growing silicon germanium (SiGe).

In some exemplary embodiments, the silicon precursor may include halogenated silane. Herein, for convenience of description, the terms of the silicon precursors and the silicon precursor may be used interchangeably. The difference between the first Ge concentration and the second Ge concentration may be controlled according to the number of halogen atoms per molecule of the halogenated silane provided as the silicon precursor. The halogen atom may be, for example, a fluorine (F) atom, a chlorine (Cl) atom, or a bromine (Br) atom, but is not limited thereto. Preferably, the halogen atom may be a chlorine (Cl) atom.

As an example, in the selective epitaxial growth process for forming the first epitaxial pattern 160 and the second epitaxial pattern 260, dichlorosilane (DCS: SiH₂Cl₂) may be provided as the silicon precursor. In this case, the difference between the first Ge concentration and the second Ge concentration may be about 0% to about 5%. As another example, in the selective epitaxial growth process, monochlorosilane (MCS: SiH₃Cl) may be provided as the silicon precursor. In this case, the difference between the first Ge concentration and the second Ge concentration may be about 5% to about 15%. As another example, in the selective epitaxial growth process, monosilane (MS: SiH₄) may be provided as the silicon precursor. In this case, the difference between the first Ge concentration and the second Ge concentration may be about 10% to about 20%.

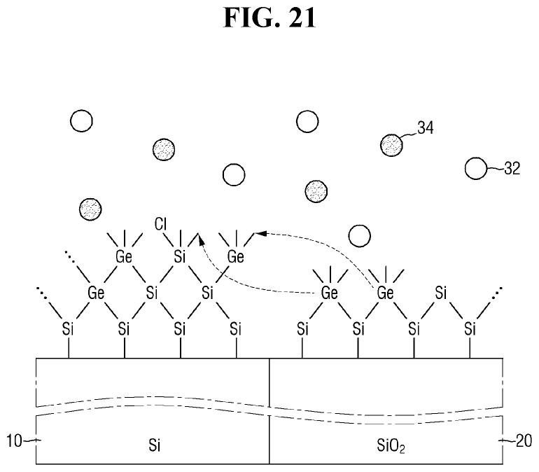

This is considered to be due to steric hindrance or the like of the silicon precursor provided in the selective epitaxial growth process. FIGS. 20 and 21 schematically illustrate growth processes of silicon germanium (SiGe) by the selective epitaxial growth process. For example, in order to grow silicon germanium (SiGe) from a silicon film 10, silicon precursors 32 and germanium precursors 34 may be provided in-situ. The silicon film 10 may share an interface with a silicon oxide film 20. In this case, at a boundary between the silicon film 10 and the silicon oxide film 20, a surface migration that some of germanium (Ge) atoms bonded to the silicon oxide film 20 migrate to the silicon film 10 may occur.

However, as illustrated in FIG. 20, when the number of halogen atoms (e.g., chlorine (Cl) atoms) per molecule of the halogenated silane provided as the silicon precursor is relatively large, a surface migration that some of germanium (Ge) atoms bonded to the silicon oxide film 20 migrate to the silicon film 10 may be limited. On the other hand, as illustrated in FIG. 21, when the number of halogen atoms (e.g., chlorine (Cl) atoms) per molecule of the halogenated silane provided as the silicon precursor is relatively small, a surface migration that some of germanium (Ge) atoms bonded to the silicon oxide film 20 migrate to the silicon film 10 may be easier.

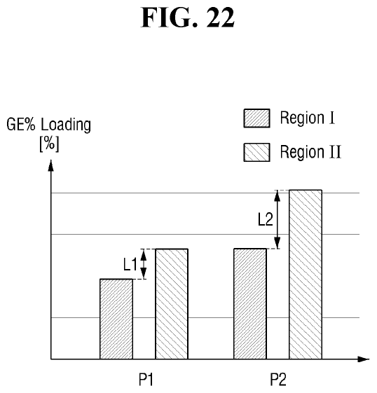

A difference in the surface migration as described above according to the types of the silicon precursors may affect a Ge concentration difference between the first region I and the second region II due to a loading effect. For example, as illustrated in FIG. 22, a Ge % loading difference L1 between the first region I and the second region II when a first silicon precursor P1 (e.g., monochlorosilane (MCS)) is used as the silicon precursor 32 may be smaller than a Ge % loading difference (L2) between the first region I and the second region II when a second silicon precursor P2 (e.g., monosilane (MS)) is used as the silicon precursor 32. As a result, the method for fabricating a semiconductor device of which performance is improved by optimizing the Ge concentrations of the epitaxial patterns for each region may be provided.

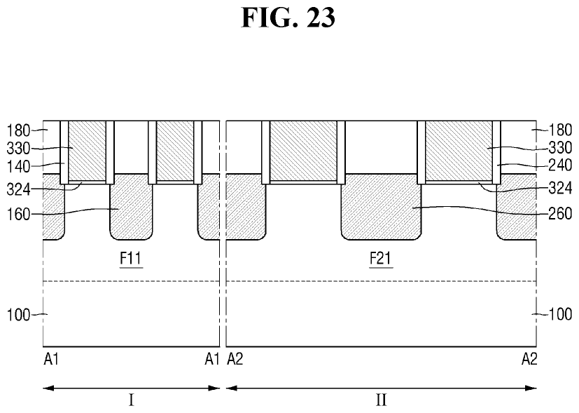

Referring to FIG. 23, a first interlayer insulating film 180 is formed on the substrate 100 and the field insulating film 105.

The first interlayer insulating film 180 may cover the dummy gate structures 324 and 330, the first epitaxial pattern 160, and the second epitaxial pattern 260. In some exemplary embodiments, the first interlayer insulating film 180 may be planarized until upper surfaces of the dummy gate electrodes 330 are exposed. The first interlayer insulating film 180 is planarized, such that the mask pattern 350 may be removed.

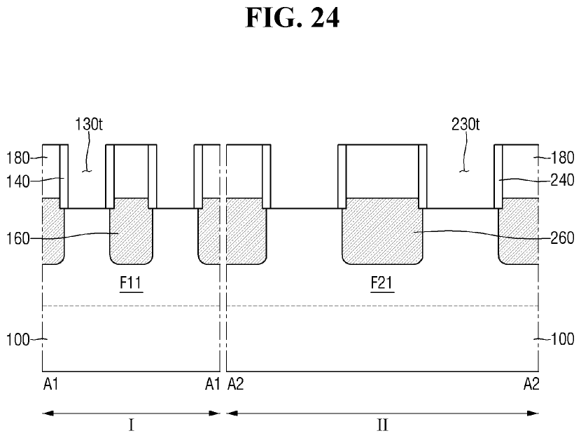

Referring to FIG. 24, the dummy gate structures 324 and 330 are removed.

The dummy gate structures 324 and 330 are removed, such that a first trench 130t exposing each of the first to third active patterns F11 to F13 and a second trench 230t exposing each of the fourth and fifth active patterns F21 and F22 may be formed. In some exemplary embodiments, side surfaces of the first trench 130t may be defined by the first gate spacers 140, and side surfaces of the second trench 230t may be defined by the second gate spacers 240.

Then, referring to FIGS. 1 to 4, first and second gate structures G11 and G12 and third and fourth gate structures G21 and G22 are formed.

For example, the first and second gate structures G11 and G12 filling the first trenches 130t of FIG. 24 may be formed, and the third and fourth gate structures G21 and G22 filling the second trenches 230t of FIG. 24 may be formed.

In some exemplary embodiments, before the first and second gate structures G11 and G12 and the third and fourth gate structures G21 and G22 are formed, a first interface film 122 may be formed on each of the first to third active patterns F11 to F13, and a second interface film 222 may be formed on each of the fourth and fifth active patterns F21 and F22.

In concluding the detailed description, those skilled in the art will appreciate that many variations and modifications may be made to the preferred embodiments without substantially departing from the principles of the present invention. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor device comprising:
a substrate including a first region and a second region;
a first active pattern extending in a first direction, on the first region;
a first gate structure extending in a second direction crossing the first direction and having a first width in the first direction, on the first active pattern;
a first epitaxial pattern disposed in the first active pattern on a side surface of the first gate structure;
a second active pattern extending in a third direction, on the second region;
a second gate structure extending in a fourth direction crossing the third direction and having a second width greater than the first width in the third direction, on the second active pattern; and
a second epitaxial pattern disposed in the second active pattern on a side surface of the second gate structure,
wherein each of the first epitaxial pattern and the second epitaxial pattern includes silicon germanium (SiGe), and
wherein the first epitaxial pattern has a first Ge concentration and the second epitaxial pattern has a second Ge concentration higher than the first Ge concentration.

2. The semiconductor device of claim 1, wherein each of the first region and the second region includes a plurality of P-channel field effect transistors (PFETs).

3. The semiconductor device of claim 1, wherein a difference between the first Ge concentration and the second Ge concentration is 5% to 20%.

4. The semiconductor device of claim 1, further comprising:
a third active pattern adjacent to the first active pattern in the second direction and extending side by side with the first active pattern, on the first region; and
a fourth active pattern adjacent to the second active pattern in the fourth direction and extending side by side with the second active pattern, on the second region,
wherein a first distance by which the first active pattern and the third active pattern are spaced apart from each other is smaller than a second distance by which the second active pattern and the fourth active pattern are spaced apart from each other.

5. The semiconductor device of claim 4, further comprising a field insulating film separating the first active pattern and the third active pattern and separating the second active pattern and the fourth active pattern, on the substrate.

6. The semiconductor device of claim 1, further comprising:
a third gate structure adjacent to the first gate structure in the first direction and extending side by side with the first gate structure, on the first region; and
a fourth gate structure adjacent to the second gate structure in the third direction and extending side by side with the second gate structure, on the second region,
wherein a third distance by which the first gate structure and the third gate structure are spaced apart from each other in the first direction is smaller than a fourth distance by which the second gate structure and the fourth gate structure are spaced apart from each other in the third direction.

7. The semiconductor device of claim 6, wherein the first epitaxial pattern is interposed between the first gate structure and the third gate structure, and
wherein the second epitaxial pattern is interposed between the second gate structure and the fourth gate structure.

8. The semiconductor device of claim 1, wherein each of the first epitaxial pattern and the second epitaxial pattern includes a plurality of epitaxial layers sequentially stacked on the substrate and having different Ge concentrations from each other.

9. The semiconductor device of claim 1, wherein each of the first epitaxial pattern and the second epitaxial pattern is formed by a selective epitaxial growth (SEG) process.

10. The semiconductor device of claim 9, wherein the first epitaxial pattern and the second epitaxial pattern are formed at the same level in a vertical direction.

11. The semiconductor device of claim 1, wherein each of the first active pattern and the second active pattern includes a fin pattern protruding from the substrate.

12. The semiconductor device of claim 1, wherein each of the first active pattern and the second active pattern includes a plurality of sheet patterns spaced apart from the substrate.

13. A semiconductor device comprising:
a substrate including a first region and a second region;
a first gate structure and a second gate structure arranged along a first direction and each extending in a second direction crossing the first direction, on the first region;
a first epitaxial pattern disposed on the substrate between the first gate structure and the second gate structure;
a third gate structure and a fourth gate structure arranged along a third direction and each extending in a fourth direction crossing the third direction, on the second region; and
a second epitaxial pattern disposed on the substrate between the third gate structure and the fourth gate structure,
wherein a first distance by which the first gate structure and the second gate structure are spaced apart from each other in the first direction is smaller than a second distance by which the third gate structure and the fourth gate structure are spaced apart from each other in the third direction,
wherein each of the first epitaxial pattern and the second epitaxial pattern includes silicon germanium (SiGe), and
wherein the first epitaxial pattern has a first Ge concentration and the second epitaxial pattern has a second Ge concentration higher than the first Ge concentration.

14. The semiconductor device of claim 13, wherein each of the first region and the second region includes a plurality of p-channel field effect transistors.

15. The semiconductor device of claim 13, wherein a difference between the first Ge concentration and the second Ge concentration is 5% to 20%.

16. The semiconductor device of claim 13, further comprising:
a first active pattern and a second active pattern extending side by side in the first direction and crossing the first gate structure and the second gate structure, on the first region; and
a third active pattern and a fourth active pattern extending side by side in the third direction and crossing the third gate structure and the fourth gate structure, on the second region,
wherein a third distance by which the first active pattern and the second active pattern are spaced apart from each other in the second direction is smaller than a fourth distance by which the third active pattern and the fourth active pattern are spaced apart from each other in the fourth direction.

17. A semiconductor device comprising:
a substrate including a first region and a second region;
a first active pattern and a second active pattern each extending side by side in a first direction, on the first region;
a first gate structure extending in a second direction crossing the first direction, on the first active pattern and the second active pattern;
a first epitaxial pattern disposed in the first active pattern on a side surface of the first gate structure;
a third active pattern and a fourth active pattern extending side by side in a third direction, on the second region;
a second gate structure extending in a fourth direction crossing the third direction, on the third active pattern and the fourth active pattern; and
a second epitaxial pattern disposed in the third active pattern on a side surface of the second gate structure,
wherein a first distance by which the first active pattern and the second active pattern are spaced apart from each other in the second direction is smaller than a second distance by which the third active pattern and the fourth active pattern are spaced apart from each other in the fourth direction,
wherein each of the first epitaxial pattern and the second epitaxial pattern includes silicon germanium (SiGe), and
wherein the first epitaxial pattern has a first Ge concentration and the second epitaxial pattern has a second Ge concentration higher than the first Ge concentration.

18. The semiconductor device of claim 17, wherein each of the first region and the second region includes a plurality of p-channel field effect transistors.

19. The semiconductor device of claim 17, wherein a difference between the first Ge concentration and the second Ge concentration is 5% to 20%.

20. The semiconductor device of claim 17, wherein the first gate structure has a first width in the first direction, and
wherein the second gate structure has a second width greater than the first width in the third direction.
